(19) United States
(12) Patent Application Publication
(10) Pub. No.: US 2026/0304662 A1
(43) Pub. Date: Oct. 1, 2026

(54) DISPLAY DEVICE

(71) Applicant: AUO Corporation, Hsinchu City (TW)

(72) Inventors: Guo-Tsai LIAU, Hsinchu City (TW); Cheng-Min Tsai, Hsinchu City (TW)

(21) Appl. No.: 19/630,853

(22) Filed: Mar. 27, 2026

(30) Foreign Application Priority Data
Mar. 31, 2025 (TW) 114112433

(51) Int. Cl. H05K 5/03; G02F 1/13357

(52) U.S. Cl. CPC H05K 5/03; G02F 1/133608; G02F 2202/28

(57) ABSTRACT

A display device includes a housing, a display module, a backlight module, a first adhesive and a second adhesive. The backlight module is stacked with the display module inside the housing. The first adhesive is adhered between the display module and the backlight module. The second adhesive is adhered between the backlight module and the housing. An upper surface of the first adhesive is entirely adhered to the display module.

### RELATED APPLICATIONS

This application claims priority to Taiwanese Application Serial Number 114112433, filed March 31, 2025, which is herein incorporated by reference in its entirety.

### BACKGROUND

### Technical Field

The present disclosure relates to display devices. More particularly, the present disclosure relates to display devices having a narrow bezel.

### Description of Related Art

With the continuous improvement of the living standards of people, the demand for display devices has been increasing. Facing to the huge consumer market for display devices, manufacturers are striving hard to improve their display devices produced in order to enhance the competitiveness of their products.

However, apart from improving the performance and efficiency of display devices, the measure to effectively enhance the practicality and aesthetics of display devices at low cost is undoubtedly an important issue to which the industry highly concerns.

### SUMMARY

A technical aspect of the present disclosure is to provide a display device, which can narrow the bezel width at low cost, thereby improving the practicality and visual effect of the display device.

According to an embodiment of the present disclosure, a display device includes a housing, a display module, a backlight module, a first adhesive and a second adhesive. The backlight module is stacked with the display module inside the housing. The first adhesive is adhered between the display module and the backlight module. The second adhesive is adhered between the backlight module and the housing. An upper surface of the first adhesive is entirely adhered to the display module.

In one or more embodiments of the present disclosure, the housing includes a wall plate and a bottom plate. The bottom plate is connected with the wall plate. The wall plate and the bottom plate together define a space. The display module is located in the space. The display module, the first adhesive, the backlight module, the second adhesive and the bottom plate are at least partially sequentially overlapped along a vertical direction.

In one or more embodiments of the present disclosure, the display module includes a display panel, a transparent cover plate and a third adhesive. The upper surface of the first adhesive is entirely adhered to the display panel. The display panel is located between the transparent cover plate and the backlight module. The third adhesive is adhered between the display panel and the transparent cover plate along the vertical direction. A lower surface of the third adhesive is entirely adhered to the display panel.

In one or more embodiments of the present disclosure, the display panel is inwardly offset relative to the transparent cover plate. The display module further includes a light-shielding adhesive. The light-shielding adhesive is connected with a side of the transparent cover plate facing to the backlight module and a side surface of the display panel.

In one or more embodiments of the present disclosure, the transparent cover plate and the wall plate are spaced apart from each other.

In one or more embodiments of the present disclosure, the first adhesive and the third adhesive are optically clear adhesives.

In one or more embodiments of the present disclosure, the backlight module includes a back plate, a side plate, a plurality of optical films, a supporting glass and a tape. The side plate is located between the optical films and the back plate. The supporting glass is stacked on a side of the optical films away from the back plate. The tape is adhered to an outer side of the side plate, a side of the supporting glass away from the back plate and a side of the back plate away from the supporting glass. The first adhesive is adhered between the display panel and the supporting glass. The second adhesive is adhered between the back plate and the bottom plate.

In one or more embodiments of the present disclosure, the supporting glass directly abuts against a side of the optical films away from the back plate.

In one or more embodiments of the present disclosure, the first adhesive at least partially covers the tape.

In one or more embodiments of the present disclosure, the housing further includes a light-absorbing layer. The light-absorbing layer is disposed on a side of the wall plate facing to the space and at least partially aligned with the display module.

According to an embodiment of the present disclosure, a display device includes a housing, a backlight module, a display module, a first adhesive and a second adhesive. The backlight module is disposed inside the housing. The display module is disposed on the backlight module. The first adhesive is adhered between the display module and the backlight module. The second adhesive is adhered between the backlight module and the housing. An edge of the display module is free from coverage by the first adhesive.

In one or more embodiments of the present disclosure, the display module includes a display panel, a transparent cover plate and a third adhesive. The first adhesive is adhered to the display panel. An edge of the display panel is free from coverage by the first adhesive. The display panel is located between the transparent cover plate and the backlight module. Third adhesive is adhered between the display panel and the transparent cover plate. The edge of the display panel is free from coverage by the third adhesive.

In one or more embodiments of the present disclosure, the housing includes a bottom plate, a wall plate and a light-absorbing layer. The backlight module is disposed on the bottom plate. The wall plate is connected to an edge of the bottom plate. The light-absorbing layer is disposed on a side of the wall plate facing to the display module and at least partially aligned with the display module.

In one or more embodiments of the present disclosure, the wall plate includes a first subsidiary wall plate and a second subsidiary wall plate. The first subsidiary wall plate has a first width. The light-absorbing layer is disposed on the first subsidiary wall plate. The second subsidiary wall plate is connected between the first subsidiary wall plate and the bottom plate. The second subsidiary wall plate has a second width. The second width is larger than the first width. An outer surface of the second subsidiary wall plate is flush with an outer surface of the first subsidiary wall plate. A vertical projection of the display module towards the bottom plate at least partially overlaps on the second subsidiary wall plate.

In one or more embodiments of the present disclosure, the display module and the light-absorbing layer form a gap there between.

The above-mentioned embodiments of the present disclosure have at least the following advantages:
(1) Since the first adhesive is adhered between the display module and the backlight module in the vertical direction, and the transparent cover plate is not in direct contact with the wall plate, the bezel width of the display device can be effectively narrowed, thereby improving the practicality and visual effect of the display device.
(2) Since the installation of the display device is simple and easy, the installation cost can be effectively reduced.

### BRIEF DESCRIPTION OF THE DRAWINGS

The disclosure can be more fully understood by reading the following detailed description of the embodiments, with reference made to the accompanying drawings as follows:

FIG. 1 is a partial cross-sectional view of a display device according to an embodiment of the present disclosure; and

FIGS. 2-3 are schematic views showing the installation process of the display device of FIG. 1.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

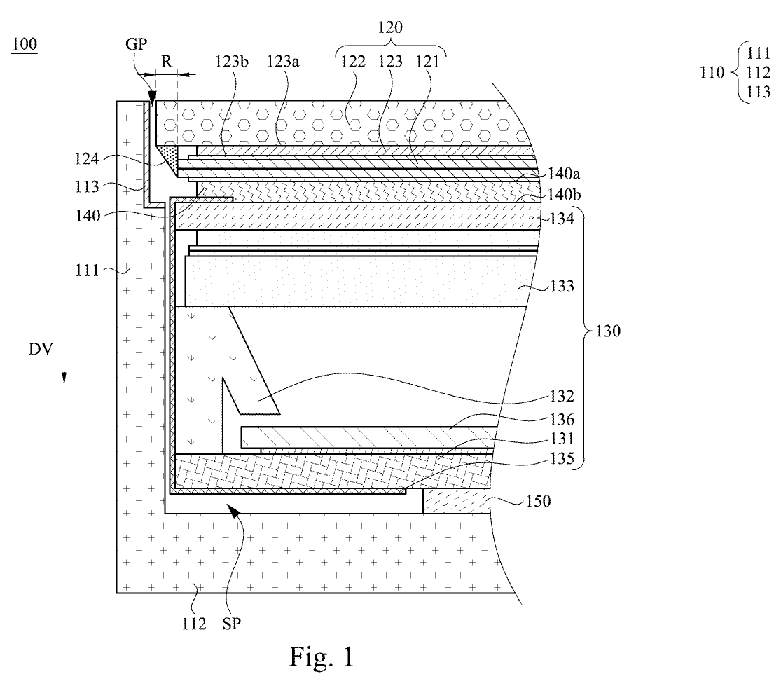

Reference is made to FIG. 1. FIG. 1 is a partial cross-sectional view of a display device 100 according to an embodiment of the present disclosure. In this embodiment, as shown in FIG. 1, a display device 100 includes a housing 110, a display module 120, a backlight module 130, a first adhesive 140 and a second adhesive 150. The backlight module 130 and the display module 120 are stacked inside the housing 110. The first adhesive 140 is adhered between the display module 120 and the backlight module 130, while the second adhesive 150 is adhered between the backlight module 130 and the housing 110. Furthermore, the first adhesive 140 has an upper surface 140a and a lower surface 140b opposite to the upper surface 140a. The lower surface 140b is entirely adhered to the backlight module 130, while the upper surface 140a is entirely adhered to the display module 120. In practical applications, the first adhesive 140 is an optically clear adhesive, such as optically clear resin, while the second adhesive 150 may be a glue or double-sided tape.

To be specific, as shown in FIG. 1, the housing 110 includes a wall plate 111 and a bottom plate 112 connected with the wall plate 111. In practice, the wall plate 111 is connected to an edge of the bottom plate 112. The wall plate 111 and the bottom plate 112 together define a space SP. The display module 120 is located in the space SP of the housing 110. It is worth to note that, in this embodiment, the display module 120, the first adhesive 140, the backlight module 130, the second adhesive 150 and the bottom plate 112 are at least partially sequentially overlapped along a vertical direction DV.

To be more specific, as shown in FIG. 1, the display module 120 includes a display panel 121, a transparent cover plate 122 and a third adhesive 123. The display panel 121 is located between the transparent cover plate 122 and the backlight module 130. The upper surface 140a of the first adhesive 140 is entirely adhered to the display panel 121. The third adhesive 123 is adhered between the display panel 121 and the transparent cover plate 122 along the vertical direction DV. In addition, the third adhesive 123 has an upper surface 123a and a lower surface 123b opposite to the upper surface 123a. The upper surface 123a is entirely adhered to the transparent cover plate 122, while the lower surface 123b is entirely adhered to the display panel 121. In other words, the first adhesive 140 and the third adhesive 123 are entirely adhered to opposite sides of the display panel 121, respectively. In practical applications, similarly, the third adhesive 123 may also be an optically clear adhesive like the first adhesive 140, such as optically clear resin.

Moreover, as shown in FIG. 1, the transparent cover plate 122 of the display module 120 and the wall plate 111 of the housing 110 are spaced apart from each other. That is, the transparent cover plate 122 and the wall plate 111 are not in direct contact with each other, and a gap GP is further formed between the transparent cover plate 122 and the wall plate 111. Since the first adhesive 140 is adhered between the display module 120 and the backlight module 130 in the vertical direction DV, and the transparent cover plate 122 is not in direct contact with the wall plate 111, the bezel width of the display device 100 can be effectively narrowed, thereby improving the practicality and visual effect of the display device 100.

Furthermore, the top end of the wall plate 111 is coplanar with or higher than the transparent cover plate 122 in the vertical direction DV. Therefore, the wall plate 111 of the housing 110 can provide complete enclosure for the display module 120, which can effectively reduce the chance of light leakage from the display device 100.

In addition, as shown in FIG. 1, the display panel 121 of the display module 120 is inwardly offset relative to the transparent cover plate 122, that is, the edge of the display panel 121 is farther away from the wall plate 111 of the housing 110 relative to the edge of the transparent cover plate 122, and an inward offset distance R is defined between the edge of the display panel 121 and the edge of the transparent cover plate 122. The inward offset distance R is practically less than 5 mm, but the present disclosure is not limited thereto. Furthermore, the display module 120 further includes a light-shielding adhesive 124. The light-shielding adhesive 124 is connected with a side of the transparent cover plate 122 facing to the backlight module 130 and a side surface of the display panel 121, in order to reduce the chance of light leakage from the display module 120.

Moreover, as shown in FIG. 1, the housing 110 further includes a light-absorbing layer 113. The light-absorbing layer 113 is disposed on a side of the wall plate 111 facing to the space SP, and the light-absorbing layer 113 is at least partially aligned with the display module 120, in order to reduce the chance of light leakage from the display device 100. In practical applications, the light-absorbing layer 113 may be a black baking paint.

On the other hand, as shown in FIG. 1, the backlight module 130 includes a back plate 131, a side plate 132, a plurality of optical films 133, a supporting glass 134 and a tape 135. The side plate 132 is located between the optical films 133 and the back plate 131. The side plate 132 may practically be a cavity reflector, while a printed circuit board 136 and light sources (not shown) are disposed on the back plate 131. The supporting glass 134 is stacked on a side of the optical films 133 away from the back plate 131 and provides a certain pressure to the optical films 133. The tape 135 is adhered to an outer side of the side plate 132, a side of the supporting glass 134 away from the back plate 131 and a side of the back plate 131 away from the supporting glass 134, in order to prevent displacement between the side plate 132, the supporting glass 134 and the back plate 131, thereby fixing the structure of the backlight module 130. According to the actual situations, the side plate 132 may further be fixed to the back plate 131 using fasteners such as screws. To be more specific, the first adhesive 140 is adhered between the display panel 121 of the display module 120 and the supporting glass 134 of the backlight module 130, while the second adhesive 150 is adhered between the back plate 131 of the backlight module 130 and the bottom plate 112 of the housing 110.

In practical applications, the side of the tape 135 adhered to the side plate 132, the supporting glass 134 and the back plate 131 is white in color, in order to provide a reflective effect. Conversely, the side of the tape 135 facing away from the side plate 132, the supporting glass 134 and the back plate 131 is black in color, in order to provide a light-absorbing effect.

It is worth to note that, in this embodiment, as shown in FIG. 1, the supporting glass 134 of the backlight module 130 directly abuts against a side of the optical films 133 away from the back plate 131. That is, there is no adhesive material between the supporting glass 134 and the optical films 133.

Furthermore, as shown in FIG. 1, the first adhesive 140 at least partially covers the tape 135 of the backlight module 130, which can effectively prevent the tape 135 from detaching from the supporting glass 134, thereby improving the structural stability of the display device 100.

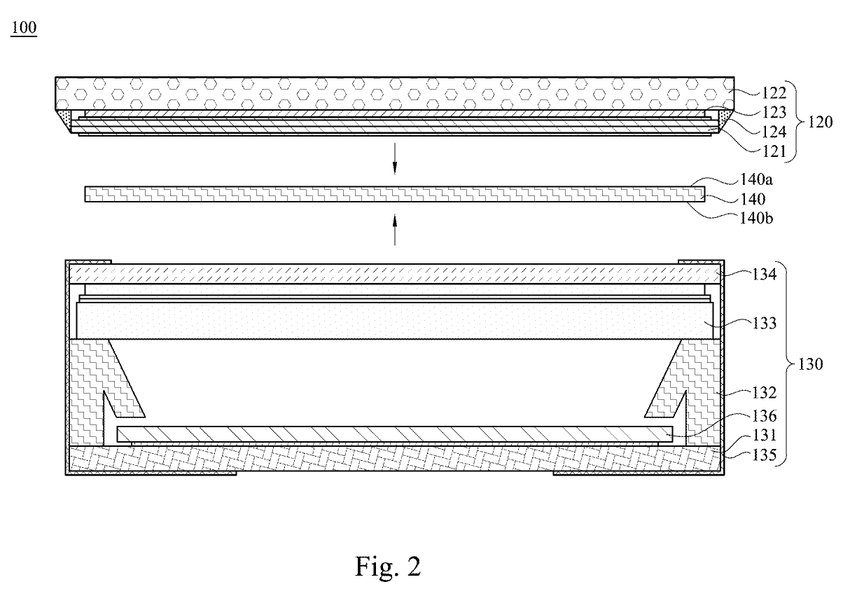

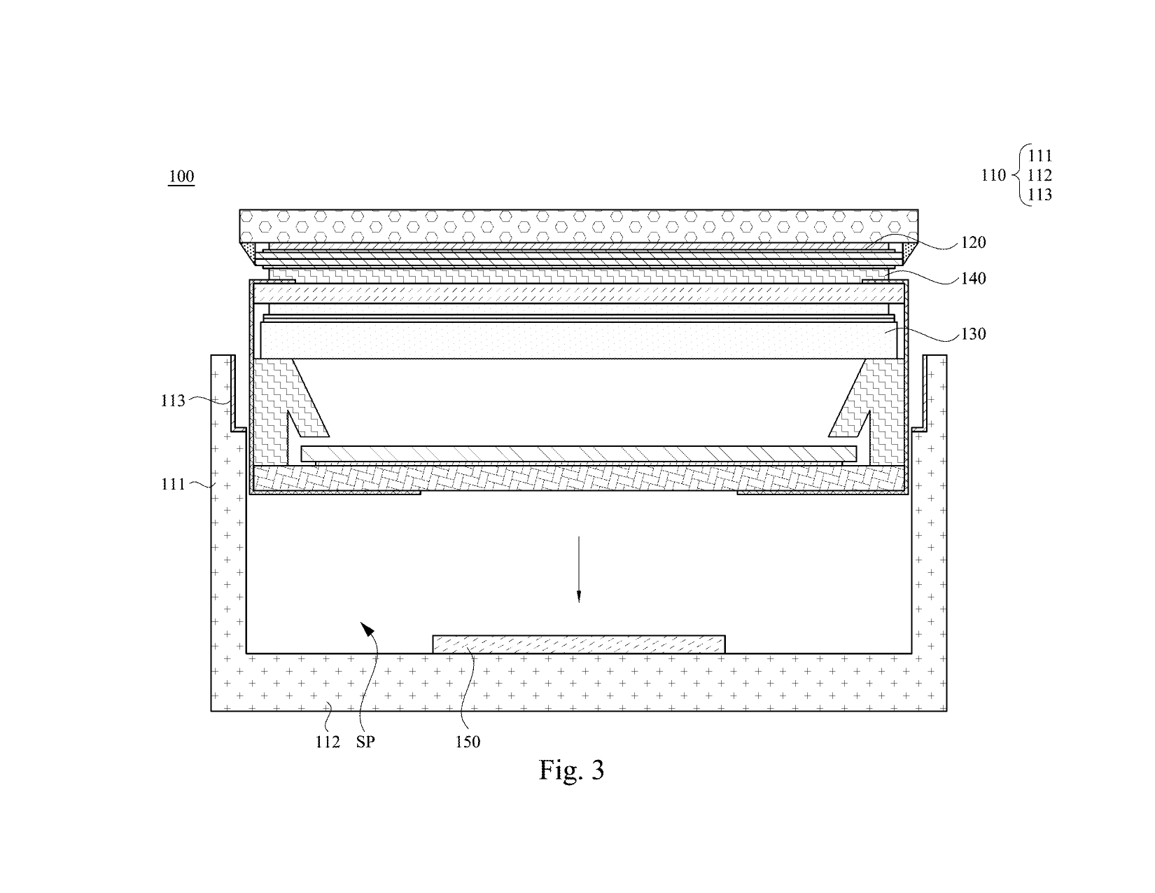

Reference is made to FIGS. 2-3. FIGS. 2-3 are schematic views showing the installation process of the display device 100 of FIG. 1. During the installation process of the display device 100, as shown in FIG. 2, the user first adheres the first adhesive 140 between the display module 120 and the backlight module 130. Afterwards, as shown in FIG. 3, the user places the display module 120 and the backlight module 130 already connected with each other into the space SP of the housing 110, and then adheres the second adhesive 150 between the backlight module 130 and the bottom plate 112 of the housing 110. At this point, the installation of the display device 100 is completed. Since the installation of the display device 100 is simple and easy, the installation cost can be effectively reduced.

In conclusion, the aforementioned embodiments of the present disclosure have at least the following advantages:
(1) Since the first adhesive is adhered between the display module and the backlight module in the vertical direction, and the transparent cover plate is not in direct contact with the wall plate, the bezel width of the display device can be effectively narrowed, thereby improving the practicality and visual effect of the display device.
(2) Since the installation of the display device is simple and easy, the installation cost can be effectively reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A display device, comprising:
a housing;
a display module;
a backlight module stacked with the display module inside the housing;
a first adhesive adhered between the display module and the backlight module; and
a second adhesive adhered between the backlight module and the housing,
wherein an upper surface of the first adhesive is entirely adhered to the display module.

2. The display device of claim 1, wherein the housing comprises a wall plate and a bottom plate connected with the wall plate, the wall plate and the bottom plate together define a space, the display module is located in the space, the display module, the first adhesive, the backlight module, the second adhesive and the bottom plate are at least partially sequentially overlapped along a vertical direction.

3. The display device of claim 2, wherein the display module comprises:
a display panel, the upper surface of the first adhesive is entirely adhered to the display panel;
a transparent cover plate, the display panel is located between the transparent cover plate and the backlight module; and
a third adhesive adhered between the display panel and the transparent cover plate along the vertical direction,
wherein a lower surface of the third adhesive is entirely adhered to the display panel.

4. The display device of claim 3, wherein the display panel is inwardly offset relative to the transparent cover plate, the display module further comprises:
a light-shielding adhesive connected with a side of the transparent cover plate facing to the backlight module and a side surface of the display panel.

5. The display device of claim 3, wherein the transparent cover plate and the wall plate are spaced apart from each other.

6. The display device of claim 3, wherein the first adhesive and the third adhesive are optically clear adhesives.

7. The display device of claim 3, wherein the backlight module comprises a back plate, a side plate, a plurality of optical films, a supporting glass and a tape, the side plate is located between the optical films and the back plate, the supporting glass is stacked on a side of the optical films away from the back plate, the tape is adhered to an outer side of the side plate, a side of the supporting glass away from the back plate and a side of the back plate away from the supporting glass, the first adhesive is adhered between the display panel and the supporting glass, the second adhesive is adhered between the back plate and the bottom plate.

8. The display device of claim 7, wherein the supporting glass directly abuts against a side of the optical films away from the back plate.

9. The display device of claim 7, wherein the first adhesive at least partially covers the tape.

10. The display device of claim 2, wherein the housing further comprises a light-absorbing layer disposed on a side of the wall plate facing to the space and at least partially aligned with the display module.

11. A display device, comprising:
a housing;
a backlight module disposed inside the housing;
a display module disposed on the backlight module;
a first adhesive adhered between the display module and the backlight module; and
a second adhesive adhered between the backlight module and the housing,
wherein an edge of the display module is free from coverage by the first adhesive.

12. The display device of claim 11, wherein the display module comprises:
a display panel, the first adhesive is adhered to the display panel, an edge of the display panel is free from coverage by the first adhesive;
a transparent cover plate, the display panel is located between the transparent cover plate and the backlight module; and
a third adhesive adhered between the display panel and the transparent cover plate,
wherein the edge of the display panel is free from coverage by the third adhesive.

13. The display device of claim 11, wherein the housing comprises:
a bottom plate, the backlight module is disposed on the bottom plate;
a wall plate connected to an edge of the bottom plate; and
a light-absorbing layer disposed on a side of the wall plate facing to the display module and at least partially aligned with the display module.

14. The display device of claim 13, wherein the wall plate comprises:
a first subsidiary wall plate having a first width, the light-absorbing layer is disposed on the first subsidiary wall plate; and
a second subsidiary wall plate connected between the first subsidiary wall plate and the bottom plate, the second subsidiary wall plate has a second width larger than the first width, an outer surface of the second subsidiary wall plate is flush with an outer surface of the first subsidiary wall plate, a vertical projection of the display module towards the bottom plate at least partially overlaps on the second subsidiary wall plate.

15. The display device of claim 13, wherein the display module and the light-absorbing layer form a gap there between.
